(19) United States
(12) Patent Application Publication
(10) Pub. No.: US 2025/0112134 A1
(43) Pub. Date: Apr. 3, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yoshihisa UCHIDA, Tokyo (JP); Shintaro ARAKI, Tokyo (JP); Tatsuya KAWASE, Tokyo (JP); Hikaru GOTO, Tokyo (JP); Yoshiaki TAKEWAKI, Fukuoka (JP)

(73) Assignee: Mitsubishi Electric Corporation, Tokyo (JP)

(21) Appl. No.: 18/770,603

(22) Filed: Jul. 11, 2024

(30) Foreign Application Priority Data
Sep. 28, 2023 (JP) 2023-167586

(51) Int. Cl. H01L 23/495; H01L 23/00; H01L 23/31; H01L 25/065

(52) U.S. Cl. CPC H01L 23/49568; H01L 23/49524; H01L 24/40; H01L 24/48; H01L 24/73; H01L 23/3107; H01L 24/32; H01L 24/92; H01L 25/0655; H01L 2224/32245; H01L 2224/40475; H01L 2224/48175; H01L 2224/73221; H01L 2224/73263; H01L 2224/73265; H01L 2224/92157; H01L 2224/92246

(57) ABSTRACT

An object of the present disclosure is to increase heat radiation properties of a semiconductor device without increasing a size of the semiconductor device. A semiconductor device includes: a base material; a semiconductor chip mounted to an upper surface of the base material; a main electrode and a signal electrode formed in regions different from each other on the semiconductor chip, respectively; a main terminal bonded to the main electrode; and a signal terminal connected to the signal electrode via a metal wire, wherein a region in the signal terminal to which the metal wire is bonded overhangs the base material while being separated from the base material.

### BACKGROUND OF THE INVENTION

### Field of the Invention

The present disclosure relates to a semiconductor device.

### Description of the Background Art

Wire bonding using a metal wire is generally used for forming an internal wiring of a semiconductor device. However, in a semiconductor device such as an in-vehicle semiconductor device which needs to have high reliability, a main terminal is directly bonded to a semiconductor chip by soldering in many cases (for example, International Publication No. 2020/245996). International publication No. 2020/245996 discloses a semiconductor module increasing adhesiveness between a semiconductor device and a heat radiation fin, thereby increasing heat radiation properties and reliability.

### SUMMARY

In a conventional technique, heat generated by power conduction of the semiconductor chip is diffused in a lateral direction mainly by a heat spreader, and is then radiated to the heat radiation fin. As an area of the heat spreader gets larger, the heat can be radiated more in the lateral direction, and can be radiated to the heat radiation fin with a larger area, however, there is a problem that a size of the semiconductor device increases.

The present disclosure is to solve the above problems, and an object is to increase heat radiation properties of a semiconductor device without increasing a size of the semiconductor device.

A semiconductor device according to the present disclosure includes a base material, a semiconductor chip, a main electrode, a signal electrode, a main terminal, and a signal terminal. The semiconductor chip is mounted on an upper surface of the base material. The main electrode and the signal electrode are formed in regions different from each other on the semiconductor chip, respectively. The main terminal is bonded to the main electrode. The signal terminal is connected to the signal electrode via a metal wire. A region in the signal terminal to which the metal wire is bonded overhangs the base material while being separated from the base material.

According to the semiconductor device of the present disclosure, even when the base material extends in the lateral direction, the base material does not interfere with the signal terminal, thus the heat radiation properties can be increased without increasing the size of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to an embodiment 1.

FIG. 2 is a plan view of the semiconductor device according to the embodiment 1.

FIG. 3 is a cross-sectional view of a semiconductor device according to a comparative example.

FIG. 4 is a plan view of a semiconductor device according to a comparative example.

FIG. 5 is a cross-sectional view illustrating a process of bonding a metal wire to a tip end of a signal terminal in a semiconductor device according to a comparative example.

FIG. 6 is a cross-sectional view illustrating a process of bonding a metal wire to a tip end of a signal terminal in the semiconductor device according to the embodiment 1.

FIG. 7 is a cross-sectional view illustrating a process of bonding the metal wire to the tip end of the signal terminal in the semiconductor device according to the embodiment 1.

FIG. 8 is a plan view illustrating a process of bonding the metal wire to the tip end of the signal terminal in the semiconductor device according to the embodiment 1.

FIG. 9 is a cross-sectional view of a semiconductor device according to a first modification example of the embodiment 1.

FIG. 10 is a cross-sectional view of a semiconductor device according to a second modification example of the embodiment 1.

FIG. 11 is a cross-sectional view of a semiconductor device according to an embodiment 2.

FIG. 12 is a plan view of the semiconductor device according to the embodiment 2.

FIG. 13 is a plan view illustrating a signal terminal mark on a heat spreader in the semiconductor device according to the embodiment 2.

### DESCRIPTION OF THE PREFERRED EMBODIMENTS

### A. Embodiment 1

### A-1. Configuration

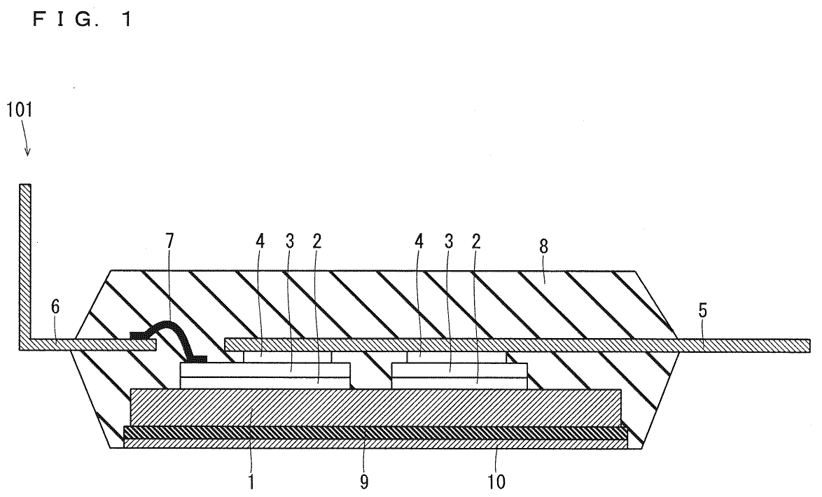

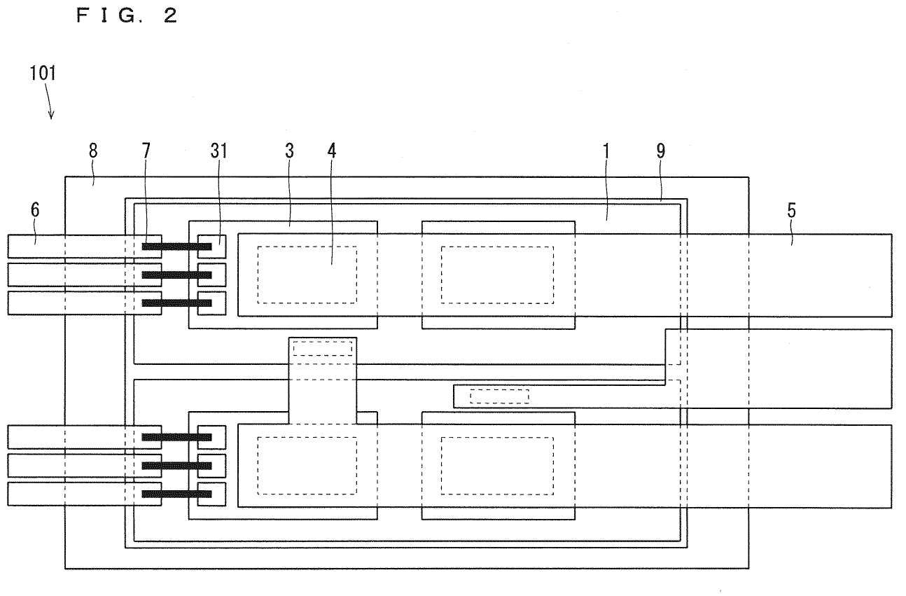

FIG. 1 is a cross-sectional view of a configuration of a semiconductor device 101 according to an embodiment 1. FIG. 2 is a plan view illustrating the configuration of the semiconductor device 101. The configuration of the semiconductor device 101 is described with reference to FIG. 1 and FIG. 2.

The semiconductor device 101 includes a heat spreader 1, a chip bonding material 2, a semiconductor chip 3, a main terminal bonding material 4, a main terminal 5, a signal terminal 6, a metal wire 7, a sealing material 8, an insulating sheet 9, and a metal foil 10.

The heat spreader 1 is a plate-like member made of Cu as a main material with a thickness of 3 mm. The heat spreader 1 is an example of a base material to which the semiconductor chip 3 is bonded. Two semiconductor chips 3 are bonded to an upper surface of the heat spreader 1 via the chip bonding material 2. The chip bonding material 2 is solder, for example. The semiconductor chip 3 is an insulated gate bipolar transistor (IGBT) and a free wheel diode (FWD), for example.

The insulating sheet 9 is attached to a lower surface of the heat spreader 1. The metal foil 10 is attached to a surface of the insulating sheet 9 on a side opposite to the heat spreader 1.

A main electrode (not shown) and a signal electrode 31 are formed in regions separated from each other on a surface of the semiconductor chip 3 on a side opposite to the heat spreader 1, that is to say, an upper surface of the semiconductor chip 3. The main electrode is an electrode inputting and outputting main current. An end portion of the main terminal 5 is bonded to the main electrode by the main terminal bonding material 4. The main terminal 5 is a terminal in which the main current flows. The main terminal bonding material 4 is solder, for example. The signal electrode 31 is an electrode inputting or outputting a control signal or a sensing signal. An end portion of the signal terminal 6 is connected to the signal electrode 31 by the metal wire 7. That is to say, the signal electrode 31 and the signal terminal 6 are connected to each other by a wire bonding method. The signal terminal 6 is a terminal in which a control signal or a sensing signal flows. The metal wire 7 is a wire made of Al as a main material with a diameter of 200 μm.

At least part of the heat spreader 1, the chip bonding material 2, the semiconductor chip 3, the main terminal bonding material 4, the main terminal 5, the signal terminal 6, the metal wire 7, the insulating sheet 9, and the metal foil 10 is sealed by the sealing material 8 made of insulative resin.

An end portion of the main terminal 5 and the signal terminal 6 which is not connected to the semiconductor chip 3 is exposed from the sealing material 8 and functions as an external terminal. Part of a lower surface of the metal foil 10 on a side opposite to the heat spreader 1 is exposed from the sealing material 8, and is connected to a heat radiation fin when the semiconductor device 101 is incorporated into a power conversion apparatus, for example.

The signal terminal 6 is separated from the heat spreader 1 by 1.5 mm in a thickness direction of the semiconductor device 101. An end portion of the signal terminal 6 to which the metal wire 7 is bonded overhangs the heat spreader 1 by 5 mm. That is to say, the end portion of the signal terminal 6 to which the metal wire 7 is bonded overlaps with the heat spreader 1 in a plan view. In the manner similar to the signal terminal 6, and end portion of the main terminal 5 also overhangs the heat spreader 1. However, the main terminal 5 overhangs the heat spreader 1 from a left side in FIG. 1, and the signal terminal 6 overhangs the heat spreader 1 from a right side in FIG. 1. In this manner, the signal terminal 6 overhangs the heat spreader 1 from a direction displaced from the main terminal 5 by 180 degrees.

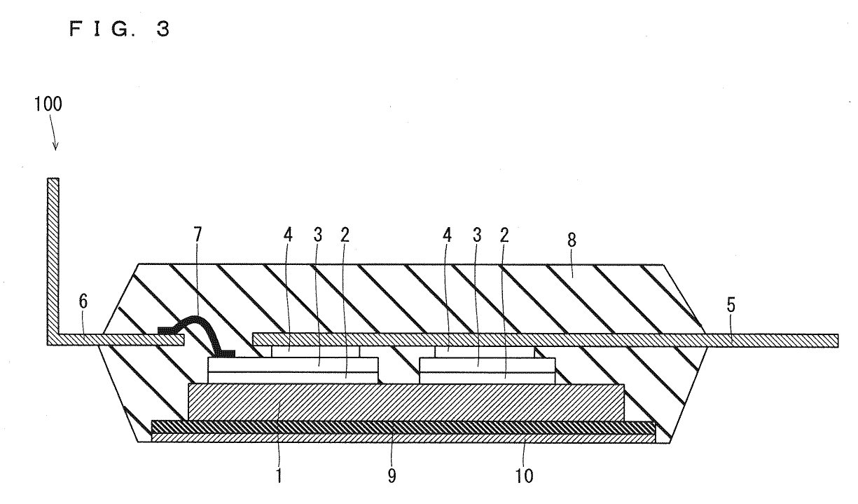

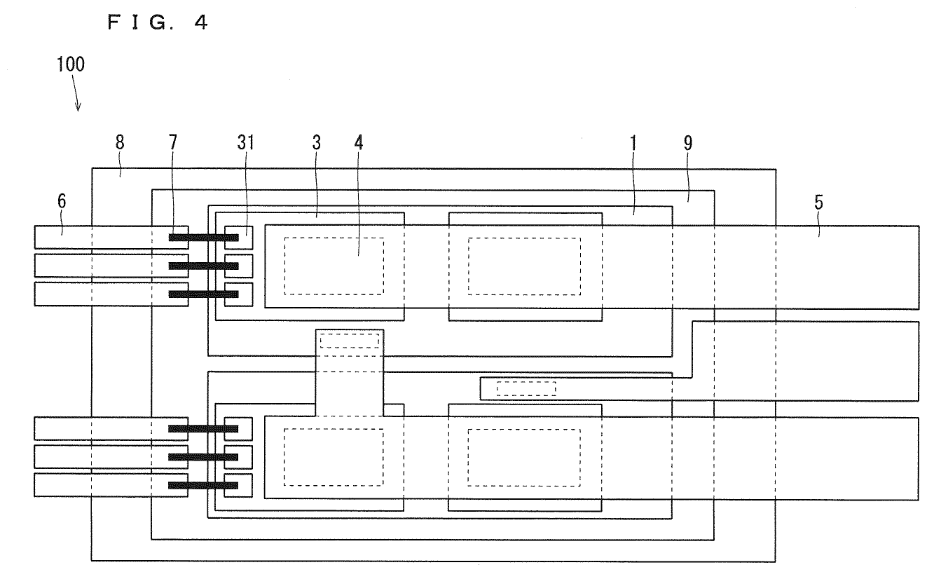

FIG. 3 is a cross-sectional view illustrating a configuration of a semiconductor device 100 according to a comparative example. FIG. 4 is a plan view illustrating the configuration of the semiconductor device 100. As illustrated in FIG. 3 and FIG. 4, an end portion of the signal terminal 6 to which the metal wire 7 is bonded in the semiconductor device 100 is disposed so as not to overlap with the heat spreader 1 in a plan view.

### A-2. Manufacturing Process

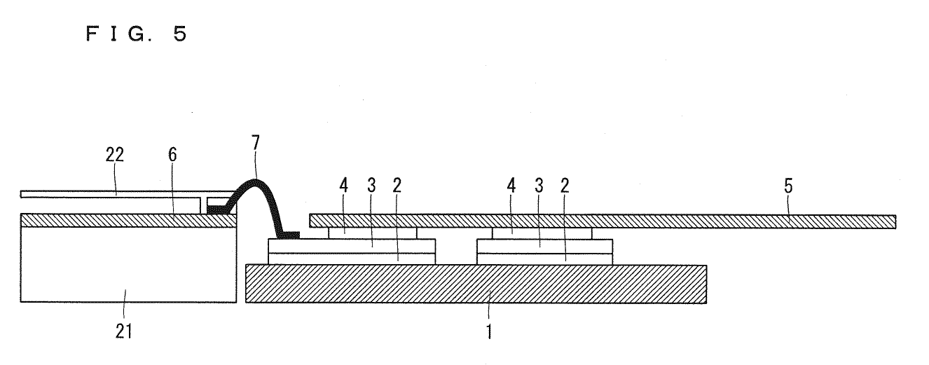

FIG. 5 is a cross-sectional view illustrating a process of manufacturing the semiconductor device 100. In the process of manufacturing the semiconductor device 100, the semiconductor chip 3 is bonded on the heat spreader 1 via the chip bonding material 2. Subsequently, the main terminal 5 is bonded to a main electrode of the semiconductor chip 3. Subsequently, the signal electrode 31 and the signal terminal 6 on the semiconductor chip 3 are bonded by the metal wire 7.

In this time, as illustrated in FIG. 5, the metal wire 7 is bonded to the signal terminal 6 while the signal terminal 6 is clamped and fixed by a lower fixing jig 21 and an upper fixing claw 22. The fixing jig 21 is disposed immediately below a region in the signal terminal 6 to which the metal wire 7 is bonded, thus the tip end of the signal terminal 6 cannot overhang the heat spreader 1. Thus, when the heat spreader 1 extends in a lateral direction to increase heat radiation properties of the semiconductor device 100, the signal terminal 6 needs to be disposed to a further outer side so as not to overlap with the heat spreader 1, and a size of the semiconductor device 100 increases. A distance from the signal terminal 6 to the semiconductor chip 3 increases, thus a length of a wiring of the metal wire 7 increases. As a result, the metal wire 7 is easily deformed in a transportation during manufacture of the semiconductor device 100 or resin sealing. When the metal wire 7 is deformed, the metal wire 7 comes contact with a member having different potential, and this causes abnormality of characteristics such as a short circuit.

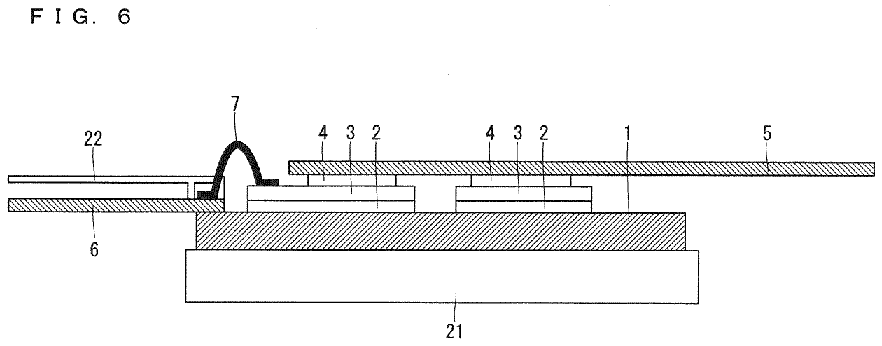

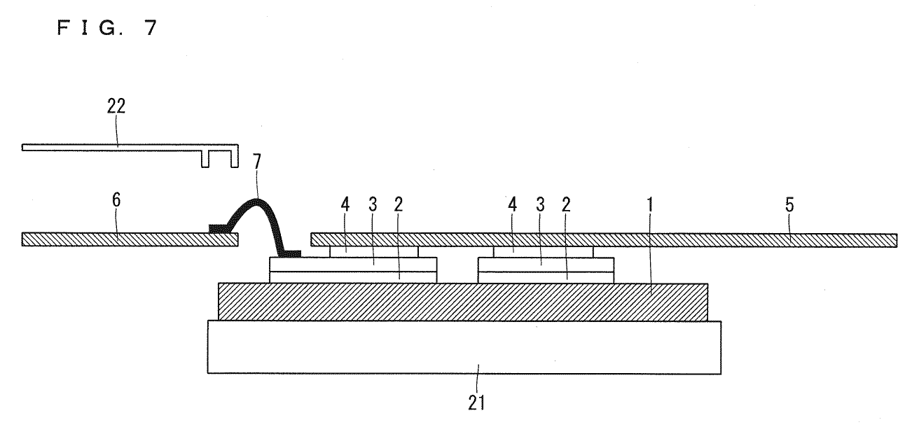

FIG. 6 and FIG. 7 are cross-sectional views illustrating a process of manufacturing the semiconductor device 101 according to the embodiment 1. In the process of manufacturing the semiconductor device 101, the semiconductor chip 3 is bonded on the heat spreader 1 via the chip bonding material 2. Subsequently, the main terminal 5 is bonded to the main electrode of the semiconductor chip 3. Subsequently, the signal electrode 31 on the semiconductor chip 3 and the signal terminal 6 are bonded by the metal wire 7.

In this time, as illustrated in FIG. 6, the metal wire 7 is bonded to the signal terminal 6 while the signal terminal 6 is clamped by the lower heat spreader 1 and the upper fixing claw 22 and the end portion thereof is pressed on the heat spreader 1. The heat spreader 1 is supported from a lower side by the fixing jig 21. That is to say, the fixing jig 21 has a role in supporting the signal terminal 6 from a lower side in the process of manufacturing the semiconductor device 100 according to the comparative example, however, the heat spreader 1 has such a role in the process of manufacturing the semiconductor device 101 according to the embodiment 1.

When the bonding of the metal wire 7 is completed, press of the signal terminal 6 by the fixing claw 22 is released as illustrated in FIG. 7. Then, elastic deformation of the signal terminal 6 caused by the press by the fixing claw 22 is restored, and the signal terminal 6 is separated from the heat spreader 1 again. In the description herein, the fixing claw 22 is pressed on the signal terminal 6 from an upper side while the fixing jig 21 is disposed on the lower side of the heat spreader 1, thereby fixing the signal terminal 6 to the heat spreader 1. However, it is also applicable that the fixing jig 21 is lifted up and the heat spreader 1 is pressed up from the lower side while the fixing claw 22 is disposed on the upper side of the signal terminal 6 to fix the signal terminal 6 to the heat spreader 1. Alternatively, it is also applicable that uplift of the fixing jig 21 and press of the fixing claw 22 are performed at the same time to fix the signal terminal 6 to the heat spreader 1.

In the semiconductor device 101, the signal terminal 6 overhangs the heat spreader 1 while being separated from the heat spreader 1. Thus, even when the heat spreader 1 extends in the lateral direction to improve the heat radiation properties, the heat spreader 1 does not interfere with the signal terminal 6, thus the signal terminal 6 needs not be moved outside of the heat spreader 1. Accordingly, the heat radiation properties of the semiconductor device 101 can be improved without increasing the size thereof. The signal terminal 6 needs not be moved outside of the heat spreader 1 in the semiconductor device 101, thus the length of the wiring of the metal wire 7 is not increased. As a result, occurrence of abnormality of characteristics in accordance with the deformation of the metal wire 7 is suppressed. The signal terminal 6 and the heat spreader 1 are separated from each other in the semiconductor device 101, thus they are not short-circuited, and an operation defect does not occur.

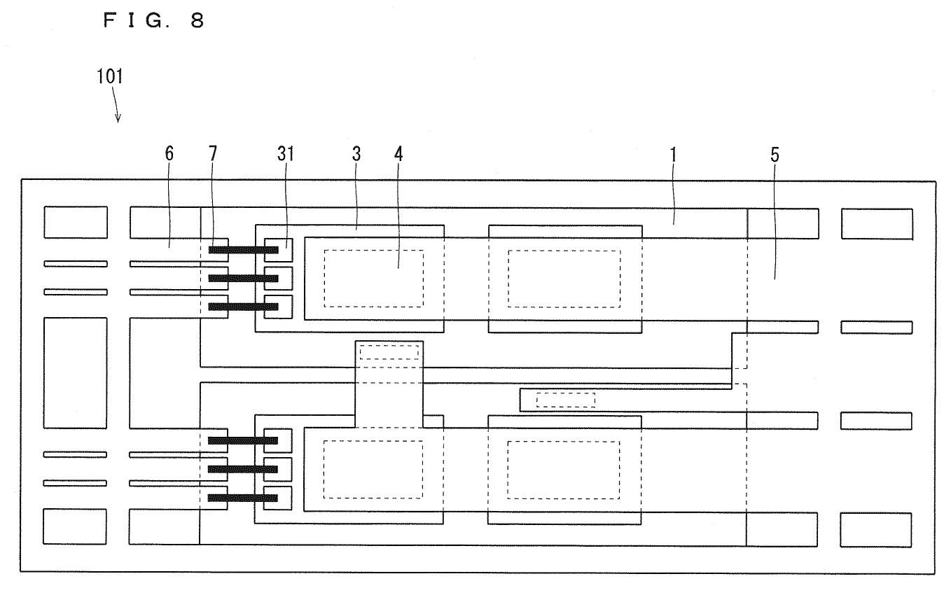

FIG. 8 is a plan view illustrating a process of manufacturing the semiconductor device 101, and illustrates a process of bonding the metal wire 7 to the signal terminal 6. The main terminal 5 and the signal terminal 6 are integrated with each other as a lead frame in the process of bonding the metal wire 7 to the signal terminal 6. This lead frame is fixed to the heat spreader 1 via the semiconductor chip 3 at a position where the main terminal 5 is bonded to the semiconductor chip 3. When the metal wire 7 is bonded to the signal terminal 6, the tip of the signal terminal 6 is pressed on the heat spreader 1 as described above. Accordingly, deformed in the lead frame is a portion from the tip end of the signal terminal 6 to a bonding part of the main terminal 5 bonded to the semiconductor chip 3 (simply referred to as “bonding part of the main terminal 5” hereinafter). As a distance from the tip end of the signal terminal 6 to the bonding part of the main terminal 5 gets large, a damage on the bonding part of the main terminal 5 caused by pressing the signal terminal 6 is reduced. In the semiconductor device 101, the signal terminal 6 overhangs the heat spreader 1 from the direction displaced from the main terminal 5 by 180 degrees as described above, thus the distance from the tip end of the signal terminal 6 to the bonding part of the main terminal 5 increases, and the damage on the bonding part of the main terminal 5 is minimally suppressed.

### A-3. First Modification Example

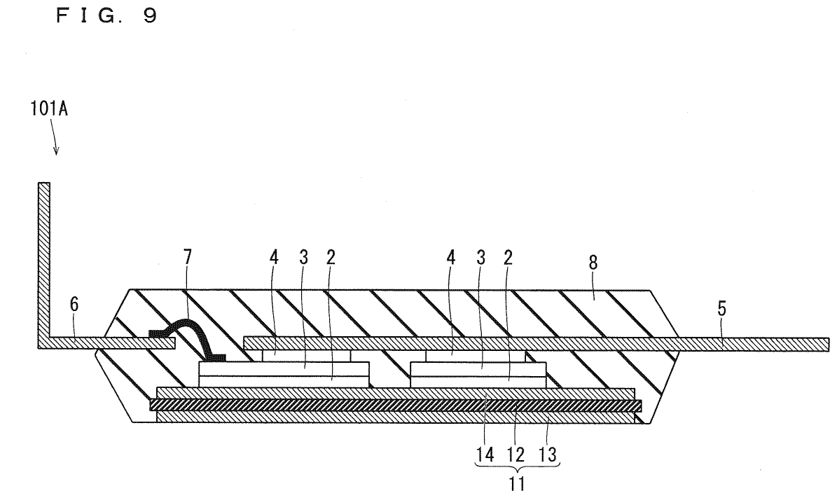

FIG. 9 is a cross-sectional view of a semiconductor device 101A according to a first modification example of the embodiment 1. A semiconductor device 101A is different from the semiconductor device 101 according to the embodiment 1 in that the semiconductor chip 3 is bonded not on the heat spreader 1 but on an insulating substrate 11. That is to say, a base material to which the semiconductor chip 3 is bonded is not the heat spreader 1 but is the insulating substrate 11 in the semiconductor device 101A. The insulating substrate 11 is made up of an insulating layer 12 made of ceramic, a conductive pattern 14 made of Cu formed on an upper surface of the insulating layer 12, and a conductive pattern 13 made of Cu formed on a lower surface of insulating layer 12. At least part of a surface of the conductive pattern 13 on a side opposite to the insulating layer 12, that is to say, at least part of a lower surface of the conductive pattern 13 is exposed from the sealing material 8. The plurality of semiconductor chips 3 are bonded to a surface of the conductive pattern 14 on a side opposite to the insulating layer 12, that is to say, an upper surface of the conductive pattern 14 via the chip bonding material 2. The insulating layer 12 may be insulative resin. Other metal such as Al may be used for the conductive patterns 13 and 14.

Also in the semiconductor device 101A, the signal terminal 6 overhangs the insulating substrate 11, thus downsizing is achieved.

### A-4. Second Modification Example

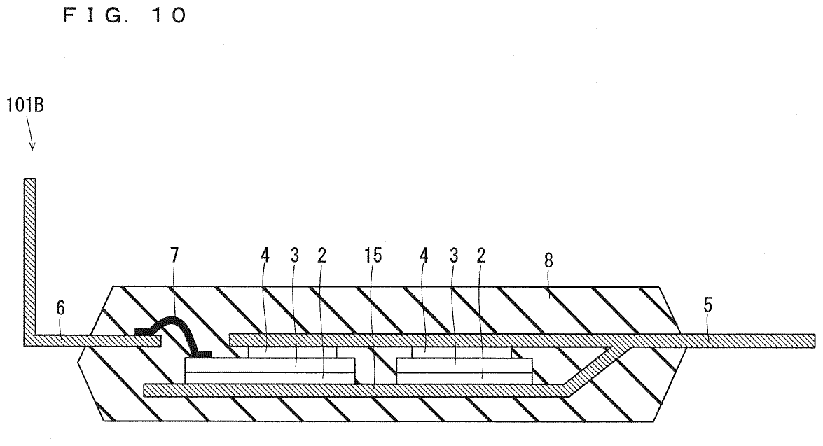

FIG. 10 is a cross-sectional view of a semiconductor device 101B according to a second modification example of the embodiment 1. The semiconductor device 101B is different from the semiconductor device 101 according to the embodiment 1 in that the semiconductor chip 3 is bonded not to the heat spreader 1 but to a die pad 15 formed by a lead frame. That is to say, a base material to which the semiconductor chip 3 is bonded is not the heat spreader 1 but is the lead frame in the semiconductor device 101B.

Also in the semiconductor device 101B, the signal terminal 6 overhangs the die pad 15, thus downsizing is achieved.

### A-5. Other Modification Example

The chip bonding material 2 and the main terminal bonding material 4 may be solder, a conductive adhesive agent, or a bonding material including a sintering Ag or Cu particles. The sintering bonding material is used for the chip bonding material 2 and the main terminal bonding material 4, thus the heat radiation properties and a life of the bonding part are improved compared with the case of the solder bonding.

The semiconductor chip 3 is not limited to an IGBT and an FWD made of Si, but may be a metal oxide semiconductor field effect transistor (MOSFET), for example. Applicable as a semiconductor material of the semiconductor chip 3 is wide bandgap semiconductor having a larger bandgap than Si, such as silicon carbide (SiC), gallium nitride (GaN), or diamond. The bandgap of the wide bandgap semiconductor is equal to or larger than 2 eV. In such a case, an operation under high temperature is required for the semiconductor device 101 to take advantage of a material having a large bandgap, and an effect of the present embodiment improving the heat radiation properties is obtained more significantly.

Described above is a case where the signal terminal 6 overhangs the heat spreader 1 by 5 mm while the signal terminal 6 and the heat spreader 1 are separated from each other by 1.5 mm. However, it is sufficient that the separation distance from the signal terminal 6 to the heat spreader 1 is equal to or larger than 0.5 mm and equal to or smaller than 2 mm, and an overhang amount thereof is equal or smaller than 20 mm. The overhang amount is a length of a portion where the signal terminal 6 and the heat spreader 1 overlap with each other in a right-left direction in FIG. 1. As long as this condition is satisfied, the signal terminal 6 is separated from the heat spreader 1 when the fixation is released after bonding the metal wire 7.

Described above is a configuration that the insulating sheet 9 and the metal foil 10 are attached to the lower surface of the heat spreader 1. However, it is also applicable that the lower surface of the heat spreader 1 is covered by the sealing material 8 to ensure insulation in the lower surface of the heat spreader 1.

Described above is a case where the signal terminal 6 overhangs the heat spreader 1 from the direction displaced from the main terminal 5 by 180 degrees. However, even when the signal terminal 6 overhangs the heat spreader 1 from a direction displaced from the main terminal 5 by 90 degrees, a distance from the tip end of the signal terminal 6 to the bonding part of the main terminal 5 can be ensured, thus obtained is the effect of suppressing the damage on the bonding part of the main terminal 5 caused by pressing the signal terminal 6.

It is preferable that an area of the heat spreader 1 is twice an area of the semiconductor chip 3 or more, and a distance from an end portion of the semiconductor chip 3 to an end portion of the heat spreader 1 is equal to or larger than a thickness of the heat spreader 1. According to this structure, heat occurring in the semiconductor chip 3 is effectively diffused in a lateral direction in the heat spreader 1, and high heat radiation properties are obtained.

In the above description, the metal wire 7 has the diameter of 200 μm, and is made of Al as the main material. However, it is sufficient that the diameter and the material of the metal wire 7 are selected in accordance with deformation of the metal wire 7 in a heat generation and resin sealing. When the metal wire 7 has the diameter ranging from 100 μm to 500 μm and is made of Al or Cu as the main material, a defect caused by the deformation of the metal wire 7 in the heat generation and resin sealing can be suppressed.

### B. Embodiment 2

### B-1. Configuration

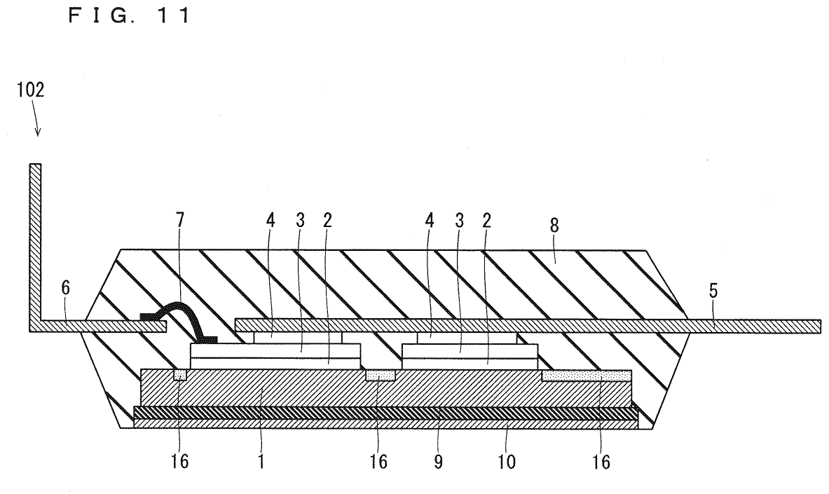

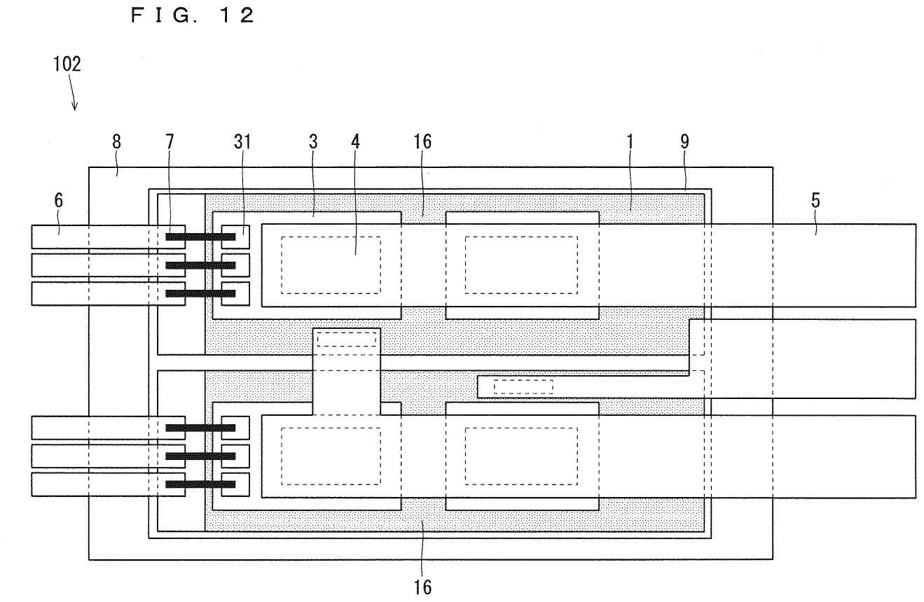

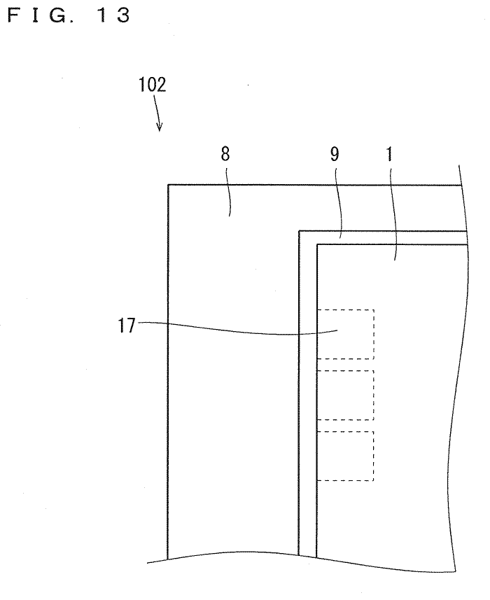

FIG. 11 is a cross-sectional view of a semiconductor device 102 according to an embodiment 2. FIG. 12 is a plan view of the semiconductor device 102. FIG. 13 is a plan view illustrating a signal terminal mark on the heat spreader 1 in the semiconductor device 102.

The semiconductor device 102 is different from the semiconductor device 101 according to the embodiment 1 only in that a dimple 16 is formed in the upper surface of the heat spreader 1. The dimple 16 is formed in at least a part of the upper surface of the heat spreader 1 other than the region where the signal terminal 6 overhangs and the region where the semiconductor chip 3 is bonded.

The dimple 16 is formed for a purpose of improving adhesiveness between the heat spreader 1 and the sealing material 8. The dimple 16 causes a void in the chip bonding material 2, thus is generally formed in the whole upper surface of the heat spreader 1 except for an area immediately below the semiconductor chip 3. However, in a case where the signal terminal 6 is pressed on the heat spreader 1 and the metal wire 7 is bonded by the wire bonding method, the metal wire 7 is bonded to the signal terminal 6 in a hollow state when the dimple 16 is located immediately below the bonding part of the metal wire 7. Thus, it is considered that bonding of the metal wire 7 is not normally completed, and the metal wire 7 is detached or bonding reliability is reduced.

With regard to this problem, a region where the signal terminal 6 on the heat spreader 1 overhangs in the semiconductor device 102 does not include the dimple 16 but is flat. Thus, even when the signal terminal 6 is pressed on the heat spreader 1 to bond the metal wire 7, bonding can be normally completed, and both bonding reliability of the metal wire 7 and adhesiveness of the sealing material 8 can be achieved.

When the signal terminal 6 is pressed on the heat spreader 1, a mark made by pressing the signal terminal 6 is formed in the heat spreader 1 as the signal terminal mark 17. The signal terminal mark is a scar or a dent having a shape similar to the signal terminal 6. In bonding the metal wire 7 on the signal terminal 6 by the wire bonding method, if the signal terminal 6 is insufficiently fixed, the bonding cannot be normally completed. With regard to this point, in the present embodiment, after the signal terminal 6 is pressed on the heat spreader 1 and the bonding of the metal wire 7 is completed, the signal terminal mark 17 is confirmed on the heat spreader 1, thus it can be confirmed that the signal terminal 6 is sufficiently fixed.

Described in the present embodiment is the case where the semiconductor chip 3 is mounted on the heat spreader 1, however, the modification example of the embodiment 1 may be applied to the present embodiment. That is to say, also applicable in the present embodiment is the insulating substrate 11 or the die pad 15 in place of the heat spreader 1.

### B-2. Effect

While the embodiments etc. have been shown and described in detail, the above embodiments are not restrictive. Various modifications and replacements can be added to the above embodiments without departing from the scope of claims.

The aspects of the present disclosure are collectively described hereinafter as appendixes.

### (Appendix 1)

A semiconductor device, comprising:
a base material;
a semiconductor chip mounted to an upper surface of the base material;
a main electrode and a signal electrode formed in regions different from each other on the semiconductor chip, respectively;
a main terminal bonded to the main electrode; and
a signal terminal connected to the signal electrode via a metal wire, wherein
a region in the signal terminal to which the metal wire is bonded overhangs the base material while being separated from the base material.

### (Appendix 2)

The semiconductor device according to Appendix 1, wherein
the base material is a heat spreader, a lead frame, or an insulating substrate.

### (Appendix 3)

The semiconductor device according to Appendix 1 or 2, wherein
a dimple is formed in at least a part of the upper surface of the base material other than a region where the signal terminal overhangs and a region where the semiconductor chip is bonded.

### (Appendix 4)

The semiconductor device according to any one of Appendixes 1 to 3, wherein
a mark made by pressing the signal terminal is formed in a position on the base material corresponding to the signal terminal.

### (Appendix 5)

The semiconductor device according to any one of Appendixes 1 to 4, wherein
a separation distance from the signal terminal to the base material is equal to or larger than 0.5 mm and equal to or smaller than 2 mm, and
an overhang amount of the signal terminal overhanging the base material is equal or smaller than 20 mm.

### (Appendix 6)

The semiconductor device according to any one of Appendixes 1 to 5, wherein
the signal terminal and the main terminal overhang the base material from directions displaced from each other by 90 degrees or 180 degrees.

### (Appendix 7)

The semiconductor device according to any one of Appendixes 1 to 6, wherein
the semiconductor chip is made of wide bandgap semiconductor as a material.

### (Appendix 8)

The semiconductor device according to any one of Appendixes 1 to 7, wherein
an area of the base material is twice an area of the semiconductor chip or more, and
a distance from an end portion of the semiconductor chip to an end portion of the base material is equal to or larger than a thickness of the base material.

### (Appendix 9)

A method of manufacturing a semiconductor device, comprising:
(a) bonding a semiconductor chip to a base material;
(b) bonding a main terminal to a main electrode of the semiconductor chip; and
(c) bonding a signal terminal to a signal electrode of the semiconductor chip via a metal wire, wherein
in the (c), the metal wire is bonded to an end portion of the signal terminal while the end portion of the signal terminal is pressed on the base material.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a base material;
a semiconductor chip mounted to an upper surface of the base material;
a main electrode and a signal electrode formed in regions different from each other on the semiconductor chip, respectively;
a main terminal bonded to the main electrode; and
a signal terminal connected to the signal electrode via a metal wire, wherein
a region in the signal terminal to which the metal wire is bonded overhangs the base material while being separated from the base material.

2. The semiconductor device according to claim 1, wherein
the base material is a heat spreader, a lead frame, or an insulating substrate.

3. The semiconductor device according to claim 1, wherein
a dimple is formed in at least a part of the upper surface of the base material other than a region where the signal terminal overhangs and a region where the semiconductor chip is bonded.

4. The semiconductor device according to claim 1, wherein
a mark made by pressing the signal terminal is formed in a position on the base material corresponding to the signal terminal.

5. The semiconductor device according to claim 1, wherein
a separation distance from the signal terminal to the base material is equal to or larger than 0.5 mm and equal to or smaller than 2 mm, and
an overhang amount of the signal terminal overhanging the base material is equal or smaller than 20 mm.

6. The semiconductor device according to claim 1, wherein
the signal terminal and the main terminal overhang the base material from directions displaced from each other by 90 degrees or 180 degrees.

7. The semiconductor device according to claim 1, wherein
the semiconductor chip is made of wide bandgap semiconductor as a material.

8. The semiconductor device according to claim 1, wherein
an area of the base material is twice an area of the semiconductor chip or more, and
a distance from an end portion of the semiconductor chip to an end portion of the base material is equal to or larger than a thickness of the base material.

9. A method of manufacturing a semiconductor device, comprising:
(a) bonding a semiconductor chip to a base material;
(b) bonding a main terminal to a main electrode of the semiconductor chip; and
(c) bonding a signal terminal to a signal electrode of the semiconductor chip via a metal wire, wherein
in the (c), the metal wire is bonded to an end portion of the signal terminal while the end portion of the signal terminal is pressed on the base material.
